(19) United States
(12) Patent Application Publication
(10) Pub. No.: US 2021/0407342 A1
(43) Pub. Date: Dec. 30, 2021

(54) DISPLAY DEVICE

(71) Applicant: SAMSUNG DISPLAY CO., LTD., Yongin-si (KR)

(72) Inventors: Juhee Song, Seoul (KR); Sena Ryu, Suwon-si (KR)

(21) Appl. No.: 17/231,091

(22) Filed: Apr. 15, 2021

(30) Foreign Application Priority Data
Jun. 26, 2020 (KR) 10-2020-0078704

(51) Int. Cl. G09F 9/30; G06F 1/16

(52) U.S. Cl. CPC G09F 9/301; G06F 1/1656; G06F 1/1616

(57) ABSTRACT

A display device includes a display panel having a folding area and a non-folding area, a first lower adhesive layer disposed under the display panel in the folding area and the non-folding area and having a first thickness, and a second lower adhesive layer disposed under the first lower adhesive layer in the folding area and the non-folding area and having a second thickness greater than the first thickness.

### CROSS-REFERENCE TO RELATED APPLICATION(S)

This application claims priority under 35 U.S.C. § 119 to Korean Patent Application No. 10-2020-0078704, filed on Jun. 26, 2020, the disclosure of which is incorporated by reference herein in its entirety.

### TECHNICAL FIELD

Embodiments of the present invention relate generally to a display device. More particularly, embodiments of the present invention relate to a display device providing robust protection against external impact.

### DISCUSSION OF RELATED ART

As display device technology advances, flexible display devices are being developed. A flexible display device may include a curved display device, a bendable display device, a foldable display device, and a rollable display device. A flexible display device may include a display panel and an adhesive layer for adhering a functional layer to the display panel. The adhesive layer may be designed to protect the display panel from external impact and to allow the display panel to be smoothly folded.

### SUMMARY

Embodiments of the present invention may provide a display device that provides robust protection against external impact.

A display device according to an embodiment includes a display panel having a folding area and a non-folding area, a first lower adhesive layer disposed under the display panel in the folding area and the non-folding area and having a first thickness, and a second lower adhesive layer disposed under the first lower adhesive layer in the folding area and the non-folding area and having a second thickness greater than the first thickness.

According to an embodiment, each of a shear modulus of the first lower adhesive layer and a shear modulus of the second lower adhesive layer is about 200 kPa to about 300 kPa at about −25° C. to about −15° C.

According to an embodiment, each of the first thickness and the second thickness is about 10 um to about 20 um.

According to an embodiment, each of a glass transition temperature of the first lower adhesive layer and a glass transition temperature of the second lower adhesive layer is about −40° C. to about −30° C.

According to an embodiment, the display device further includes a third lower adhesive layer disposed under the second lower adhesive layer in the folding area and the non-folding area and having a third thickness greater than the second thickness.

According to an embodiment, each of a shear modulus of the first lower adhesive layer, a shear modulus of the second lower adhesive layer, and a shear modulus of the third lower adhesive layer is about 200 kPa to about 300 kPa at about −25° C. to about −15° C.

According to an embodiment, the first thickness, the second thickness, and the third thickness is about 10 um to about 20 um.

According to an embodiment, a glass transition temperature of the first lower adhesive layer, a glass transition temperature of the second lower adhesive layer, and a glass transition temperature of the third lower adhesive layer is about −40° C. to about −30° C.

According to an embodiment, the display device further includes an upper adhesive layer disposed on the display panel in the folding area and the non-folding area.

According to an embodiment, a shear modulus of the upper adhesive layer is smaller than a shear modulus of the first lower adhesive layer and a shear modulus of the second lower adhesive layer.

According to an embodiment, the shear modulus of the upper adhesive layer is about 100 kPa to about 150 kPa at about −25° C. to about −15° C.

According to an embodiment, a third thickness of the upper adhesive layer is greater than each of the first thickness and the second thickness.

According to an embodiment, the third thickness of the upper adhesive layer is about 40 um to about 50 um.

According to an embodiment, a glass transition temperature of the upper adhesive layer is smaller than each of a glass transition temperature of the first lower adhesive layer and a glass transition temperature of the second lower adhesive layer.

According to an embodiment, the glass transition temperature of the upper adhesive layer is smaller than about −40° C.

A display device according to an embodiment includes a display panel having a folding area and a non-folding area, an upper adhesive layer disposed above the display panel in the folding area and the non-folding area, and a lower adhesive layer disposed under the display panel in the folding area and the non-folding area and having a thickness smaller than a thickness of the upper adhesive layer.

According to an embodiment, a shear modulus of the upper adhesive layer is smaller than a shear modulus of the lower adhesive layer.

According to an embodiment, a thickness of the upper adhesive layer is about 40 um to about 50 um, and a thickness of the lower adhesive layer is about 10 um to about 20 um.

According to an embodiment, a glass transition temperature of the upper adhesive layer is less than about −40° C., and a glass transition temperature of the lower adhesive layer is about −40° C. to about −30° C.

A display device according to an embodiment includes a display panel including a first non-folding area, a second non-folding area, and a folding area positioned between the first non-folding area and the second non-folding area. The display device further includes an upper adhesive layer disposed above the display panel and overlapping the folding area. The display device further includes a first lower adhesive layer disposed under the display panel, overlapping the folding area, having a thickness smaller than a thickness of the upper adhesive layer, and having a shear modulus greater than a shear modulus of the upper adhesive layer. The display device further includes a second lower adhesive layer disposed under the first lower adhesive layer, overlapping the folding area, having a thickness smaller than the thickness of the upper adhesive layer and greater than the thickness of the first lower adhesive layer, and having a shear modulus greater than the shear modulus of the upper adhesive layer.

Therefore, the display device according to embodiments may include a first lower adhesive layer disposed under a display panel and having a first thickness, and a second lower adhesive layer disposed under the first lower adhesive layer and having a second thickness smaller than the first thickness. The first and second lower adhesive layers may support the display panel so that the display panel is not damaged by an external impact, may reduce a stress applied to the display panel, and may assist in recovery of the display panel.

### BRIEF DESCRIPTION OF THE DRAWINGS

The above and other features of the present invention will become more apparent by describing in detail embodiments thereof with reference to the accompanying drawings, in which:

FIG. 1 is a plan view illustrating a display device according to an embodiment.

FIG. 2 is a cross-sectional view illustrating a bent shape of the display device of FIG. 1.

FIG. 3 is a cross-sectional view taken along line I-I′ of FIG. 1.

FIG. 4 is a cross-sectional view illustrating a display panel included in the display device of FIG. 1.

FIGS. 5 and 6 are diagrams illustrating a pen-drop test result according to comparative examples and an embodiment of the present invention.

FIGS. 7 and 8 are diagrams illustrating a strain test result according to comparative examples and an embodiment of the present invention.

### DETAILED DESCRIPTION

Embodiments of the present invention will be described more fully hereinafter with reference to the accompanying drawings. Like reference numerals may refer to like elements throughout the accompanying drawings.

The term “about” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations as understood by one of the ordinary skill in the art, or within ±30%, 20%, 10% or 5% of the stated value. Further, it is to be understood that while parameters may be described herein as having “about” a certain value, according to embodiments, the parameter may be exactly the certain value or approximately the certain value within a measurement error as would be understood by a person having ordinary skill in the art.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below.

It will be understood that when a component such as a film, a region, a layer, or an element, is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationship between components should be interpreted in a like fashion.

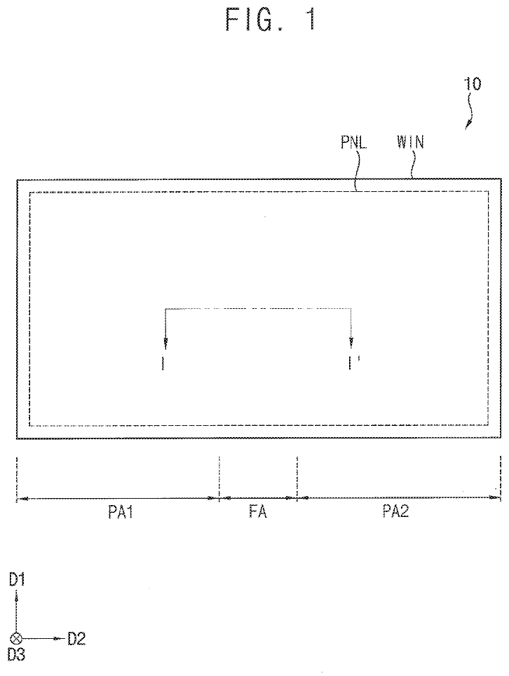

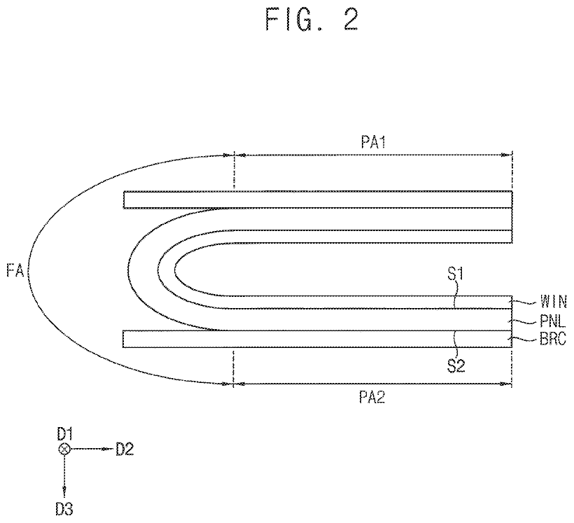

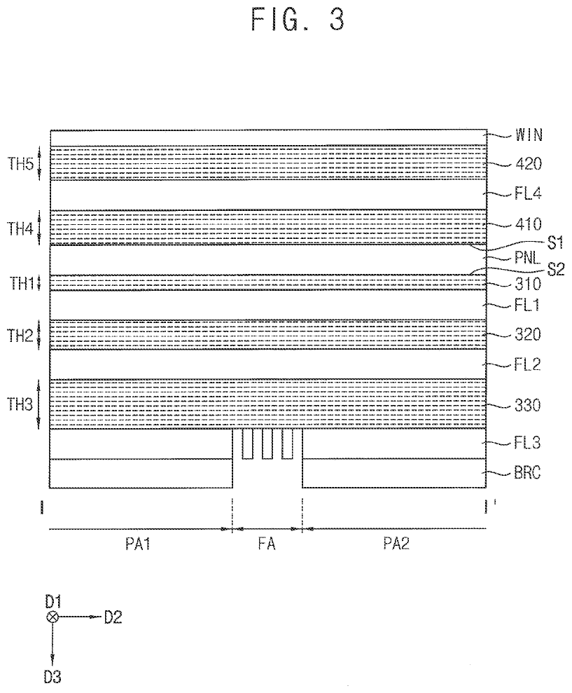

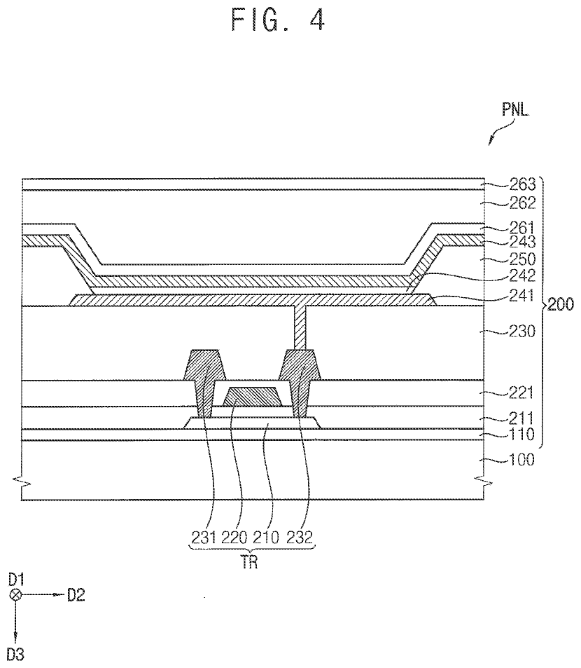

FIG. 1 is a plan view illustrating a display device according to an embodiment. FIG. 2 is a cross-sectional view illustrating a bent shape of the display device of FIG. 1. FIG. 3 is a cross-sectional view taken along line I-I′ of FIG. 1. FIG. 4 is a cross-sectional view illustrating a display panel included in the display device of FIG. 1.

Referring to FIGS. 1, 2, and 3, the display device 10 according to an embodiment may include a display panel PNL, a first lower adhesive layer 310, a first functional layer FL1, a second lower adhesive layer 320, a second functional layer FL2, a third lower adhesive layer 330, a third functional layer FL3, a bracket BRC, a first upper adhesive layer 410, a fourth functional layer FL4, a second upper adhesive layer 420, and a window WIN. The display device 10 may extend in a first direction D1, a second direction D2, and a third direction D3. The third direction D3 may refer to a thickness direction of the display device 10.

The display panel PNL may include a plurality of pixels, and each of the pixels may emit light. The display panel PNL may display an image through the pixels. For example, the display panel PNL may include an upper surface S1 and a lower surface S2 opposite to the upper surface S1, and the pixels may emit light toward the upper surface S1. Accordingly, the image may be displayed on the upper surface S1 of the display panel PNL.

In an embodiment, the display panel PNL may include a first flat area PA1, a second flat area PA2, and a folding area FA. The folding area FA may be positioned between the first flat area PA1 and the second flat area PA2. The first flat area PA1 and the second flat area PA2 may be areas of the display panel PNL that are not bendable or foldable, and the folding area FA may be an area of the display panel PNL that is bendable or foldable. The first flat area PA1 may also be referred to herein as a first non-folding area, the second flat area PA2 may also be referred to herein as a second non-folding area, and the first and second flat areas PA1 and PA2 may be collectively referred to herein as a non-folding area.

The display panel PNL may be folded or unfolded in the folding area FA. For example, as shown in FIG. 2, the display panel PNL may be folded in the folding area FA. As a result, when the display device 10 is not in use, a user may fold and conveniently carry the display device 10. When the display device 10 is in use, the display panel PNL may be unfolded in the folding area FA, as shown in FIG. 1, and the upper surface S1 of the display device 10 may be exposed to the user, allowing the user to watch an image displayed on the upper surface S1.

According to embodiments, the display device 10 may have an in-folding structure or an out-folding structure. For example, as shown in FIG. 2, the display device 10 may have an in-folding structure in which the upper surface S1 faces itself when folded. For example, the upper surface S1 may be folded toward itself when a display device 10 having an in-folding structure is folded. In addition, according to embodiments, the display device 10 may have an out-folding structure in which the upper surface S1 is folded away from itself and is exposed to the user when folded.

However, the display panel PNL is not limited to the above. For example, according to embodiments, the display panel PNL may include a plurality of folding areas, and may have an asymmetric structure in which sizes of flat areas are different from each other. In addition, when the display panel PNL includes a plurality of folding areas, the display panel PNL may utilize both in-folding and out-folding structures.

Referring to FIG. 4, the display panel PNL may include a substrate 100, a buffer layer 110, and a display structure 200. The display structure 200 may include an active pattern 210, a first insulating layer 211, a gate electrode 220, a second insulating layer 221, a source electrode 231, a drain electrode 232, a via insulating layer 230, a first electrode 241, an emission layer 242, a second electrode 243, a pixel defining layer 250, a first inorganic layer 261, an organic layer 262, and a second inorganic layer 263.

The substrate 100 may include, for example, glass, quartz, plastic, etc. In an embodiment, the substrate 100 may be a plastic substrate for implementing a flexible display device, and may include, for example, polyimide. For example, the substrate 100 may have a structure in which at least one polyimide layer and at least one barrier layer are alternately stacked.

The buffer layer 110 may be disposed on the substrate 100. The buffer layer 110 may prevent diffusion of metal atoms or impurities from the substrate 100 to the active pattern 210.

The active pattern 210 may be disposed on the buffer layer 110. The active pattern 210 may include, for example, a silicon semiconductor, a metal oxide semiconductor, etc. The first insulating layer 211 may include an insulating material and may cover the active pattern 210. The gate electrode 220 may include, for example, a metal, an alloy, a conductive metal oxide, etc., and may be disposed on the first insulating layer 211. The second insulating layer 221 may include an insulating material and may cover the gate electrode 220. The source electrode 231 and the drain electrode 232 may include, for example, a metal, an alloy, a conductive metal oxide, etc., and may be disposed on the second insulating layer 221. The via insulating layer 230 may cover the source and drain electrodes 231 and 232, may include an organic insulating material, and may have a substantially flat top surface.

The active pattern 210, the gate electrode 220, the source electrode 231, and the drain electrode 232 may form a transistor TR. The transistor TR is controlled by a gate signal (or a scan signal) provided to the gate electrode 220, and a voltage (or a signal) input to the source electrode 231 may be output to the drain electrode 232.

The first electrode 241 may be disposed on the via insulating layer 230. The first electrode 241 may receive a first voltage from the drain electrode 232. The pixel defining layer 250 may be disposed on the via insulating layer 230, and an opening partially exposing an upper surface of the first electrode 241 may be formed in the pixel defining layer 250. The emission layer 242 may cover the first electrode 241 and may be disposed in the opening. The second electrode 243 may be disposed on the emission layer 242 and may receive a second voltage.

Due to a voltage difference between the first voltage and the second voltage, light may be emitted from the emission layer 242. Accordingly, the first electrode 241, the emission layer 242, and the second electrode 243 may be defined as an organic light emitting diode.

A thin film encapsulation layer may be disposed on the second electrode 242. The thin film encapsulation layer may have a structure in which the first inorganic layer 261, the organic layer 262, and the second inorganic layer 263 are alternately stacked, which may prevent penetration of moisture and oxygen into the display device 10.

Referring back to FIG. 3, the first lower adhesive layer 310 may be disposed under the display panel PNL. For example, the first lower adhesive layer 310 may be disposed on the lower surface S2 of the display panel PNL. For example, the first lower adhesive layer 310 may directly contact the lower surface S2 of the display panel PNL. The first lower adhesive layer 310 may overlap the first flat area PA1, the second flat area PA2, and the folding area FA.

The first lower adhesive layer 310 may support the display panel PNL so that the display panel PNL is not damaged by an external impact. In addition, the first lower adhesive layer 310 may adhere the first functional layer FL1 to the display panel PNL. For example, the first lower adhesive layer 310 may directly contact the lower surface S2 of the display panel PNL and the first functional layer FL1, thus bonding the first functional layer FL1 to the lower surface S2 of the display panel PNL. In addition, when the display panel PNL is folded, the first lower adhesive layer 310 may reduce a stress applied to the display panel PNL. In addition, when the display panel PNL is unfolded, the first lower adhesive layer 310 may assist in recovery of the display panel PNL and may remove a waviness that may be visually recognized by the user.

In an embodiment, the first lower adhesive layer 310 may be an organic adhesive member. For example, the first lower adhesive layer 310 may be an optically clear adhesive (“OCA”), an optically clear resin (“OCR”), a pressure sensitive adhesive (“PSA”), etc. When the first lower adhesive layer 310 is a PSA, the PSA may be implemented with, for example, an acrylate-based adhesive, a urethane-based adhesive, or a silicone-based adhesive.

In an embodiment, a shear modulus of the first lower adhesive layer 310 may be about 200 kPa to about 300 kPa at about −25° C. to about −15° C.

The shear modulus may be a proportional constant between a shearing stress and a shearing deformation, when a shearing deformation is generated in a material. The shearing deformation may be generated when a shear force is applied to the material within an elastic range of the material.

As the shear modulus of the first lower adhesive layer 310 increases, the first lower adhesive layer 310 may support the display panel PNL so that the display panel PNL is not damaged by an external impact. However, as the shear modulus of the first lower adhesive layer 310 decreases, the first lower adhesive layer 310 may reduce the stress applied to the display panel PNL so that the display panel PNL may be assisted in recovery (e.g., recovery of the display panel PNL when transitioning from a folded state to an unfolded state may be improved).

In an embodiment, the first lower adhesive layer 310 may include an elastomer, a cross-linker, and an adhesive resin. The elastomer may have elasticity, and may include, for example, at least one of silicone rubber, urethane rubber, acrylic rubber, styrene-butadiene rubber, polyvinyl chloride, ethylene-propylene copolymer, ethylene-butene copolymer, and ethylene-vinyl acetate copolymer. The elastomer may be cured through thermal curing or UV curing. Curing the elastomer through thermal curing may result in the first lower adhesive layer 310 having a small thickness. The cross-linker may include, for example, a functional group, and the functional group may include at least one of, for example, an alkoxy silane group, a carboxyl group, an acid anhydride group, a vinyl ether group, an amine group, a carbonyl group, an isocyanate group, an epoxy group, an aziridinyl group, a carbodiimide group, and an oxazoline group. The adhesive resin may include, for example, at least one of an acrylic adhesive resin, a silicone adhesive resin, a rubber adhesive resin, a polyester adhesive resin, and a urethane adhesive resin. By properly mixing the elastomer, the cross-linker, and the adhesive resin, physical properties (e.g., shear modulus, creep, adhesive force, etc.) of the first lower adhesive layer 310 may be adjusted.

The first functional layer FL1 may be disposed on a lower surface of the first lower adhesive layer 310. For example, the first functional layer FL1 may directly contact the lower surface of the first lower adhesive layer 310. The first functional layer FL1 may overlap the first flat area PA1, the second flat area PA2, and the folding area FA.

In an embodiment, the first functional layer FL1 may be a protective film. For example, the first functional layer FL1 may prevent penetration of moisture and oxygen into the display device 10. In addition, the first functional layer FL1 may support the substrate 100, which is flexible. For example, the first functional layer FL1 may prevent the substrate 100 from sagging in the folding area FA. In addition, the first functional layer FL1 may absorb an impact applied to the display panel PNL, thus protecting the display panel PNL from damage.

In an embodiment, the first functional layer FL1 may include plastic. For example, the first functional layer FL1 may include polyimide (“PI”), polyethersulfone (“PS”), polyacrylate (“PAR”), polyetherimide (“PEI”), polyethylenenaphthalate (“PEN”), polyphenylene sulfide (“PPS”), polyarylate, polycarbonate (“PC”), poly(arylene ethersulfone), polyethylene terephthalate (“PET”), etc.

The second lower adhesive layer 320 may be disposed under the first lower adhesive layer 310. For example, the second lower adhesive layer 320 may be disposed on a lower surface of the first functional layer FL1. For example, the second lower adhesive layer 320 may directly contact the lower surface of the first functional layer FL1. The second lower adhesive layer 320 may overlap the first flat area PA1, the second flat area PA2, and the folding area FA.

The second lower adhesive layer 320 may support the display panel PNL so that the display panel PNL is not damaged by an external impact. In addition, the second lower adhesive layer 320 may adhere the second functional layer FL2 to the first functional layer FL1. For example, the second lower adhesive layer 320 may directly contact the lower surface of the first functional layer FL1 and the upper surface of the second functional layer FL2, thus bonding the lower surface of the first functional layer FL1 to the upper surface of the second functional layer FL2. In addition, when the display panel PNL is folded, the second lower adhesive layer 320 may reduce a stress applied to the display panel PNL. In addition, when the display panel PNL is unfolded, the second lower adhesive layer 320 may assist in recovery of the display panel PNL and may remove a waviness that may be visually recognized by the user.

In an embodiment, the second lower adhesive layer 320 may be an organic adhesive member. For example, the second lower adhesive layer 320 may be an OCA, an OCR, a PSA, etc. When the second lower adhesive layer 320 is a PSA, the PSA may be implemented with, for example, an acrylate-based adhesive, a urethane-based adhesive, or a silicone-based adhesive.

In an embodiment, a shear modulus of the second lower adhesive layer 320 may be about 200 kPa to about 300 kPa at about −25° C. to about −15° C.

As the shear modulus of the second lower adhesive layer 320 increases, the second lower adhesive layer 320 may support the display panel PNL so that the display panel PNL is not damaged by an external impact. However, as the shear modulus of the second lower adhesive layer 320 decreases, the second lower adhesive layer 320 may reduce the stress applied to the display panel PNL so that the display panel PNL may be assisted in recovery (e.g., recovery of the display panel PNL when transitioning from a folded state to an unfolded state may be improved).

In an embodiment, the second lower adhesive layer 320 may include an elastomer, a cross-linker, and an adhesive resin. The elastomer may have elasticity, and may include, for example, at least one of silicone rubber, urethane rubber, acrylic rubber, styrene-butadiene rubber, polyvinyl chloride, ethylene-propylene copolymer, ethylene-butene copolymer, and ethylene-vinyl acetate copolymer. The elastomer may be cured through thermal curing or UV curing. Curing the elastomer through thermal curing may result in the second lower adhesive layer 320 having a small thickness. The cross-linker may include, for example, a functional group, and the functional group may include at least one of, for example, an alkoxy silane group, a carboxyl group, an acid anhydride group, a vinyl ether group, an amine group, a carbonyl group, an isocyanate group, an epoxy group, an aziridinyl group, a carbodiimide group, and an oxazoline group. The adhesive resin may include, for example, at least one of an acrylic adhesive resin, a silicone adhesive resin, a rubber adhesive resin, a polyester adhesive resin, and a urethane adhesive resin. By properly mixing the elastomer, the cross-linker, and the adhesive resin, physical properties (e.g., shear modulus, creep, adhesive force, etc.) of the second lower adhesive layer 320 may be adjusted.

The second functional layer FL2 may be disposed on a lower surface of the second lower adhesive layer 320. For example, the second functional layer FL2 may directly contact the lower surface of the second adhesive layer 320. The second functional layer FL2 may overlap the first flat area PA1, the second flat area PA2, and the folding area FA.

In an embodiment, the second functional layer FL2 may be a buffer member. For example, the second functional layer FL2 may protect the display panel PNL by buffering an external shock applied to the display panel PNL.

In an embodiment, the second functional layer FL2 may include a material capable of buffering by containing air, such as, for example, a cushion or a sponge. In addition, to allow for the repeated folding and unfolding of the display panel PNL, the second functional layer FL2 may include a flexible material. For example, the second functional layer FL2 may include acrylic resin, polyurethane, thermoplastic polyurethane, latex, polyurethane foam, polystyrene foam, etc.

The third lower adhesive layer 330 may be disposed under the second lower adhesive layer 320. For example, the third lower adhesive layer 330 may be disposed on a lower surface of the second functional layer FL2. For example, the third lower adhesive layer 330 may directly contact the lower surface of the second functional layer FL2. The third lower adhesive layer 330 may overlap the first flat area PA1, the second flat area PA2, and the folding area FA.

The third lower adhesive layer 330 may support the display panel PNL so that the display panel PNL is not damaged by an external impact. In addition, the third lower adhesive layer 330 may adhere the third functional layer FL3 to the second functional layer FL2. For example, the third lower adhesive layer 330 may directly contact the lower surface of the second functional layer FL2 and the upper surface of the third functional layer FL3, thus bonding the second functional layer FL2 to the third functional layer FL3. In addition, when the display panel PNL is folded, the third lower adhesive layer 330 may reduce a stress applied to the display panel PNL. In addition, when the display panel PNL is unfolded, the third lower adhesive layer 330 may assist in recovery of the display panel PNL and may remove a waviness that may be visually recognized by the user.

In an embodiment, the third lower adhesive layer 330 may be an organic adhesive member. For example, the third lower adhesive layer 330 may be an OCA, an OCR, a PSA, etc. When the third lower adhesive layer 330 is a PSA, the PSA may be implemented with, for example, an acrylate-based adhesive, a urethane-based adhesive, or a silicone-based adhesive.

In an embodiment, a shear modulus of the third lower adhesive layer 330 may be about 200 kPa to about 300 kPa at about −25° C. to about −15° C.

As the shear modulus of the third lower adhesive layer 330 increases, the third lower adhesive layer 330 may support the display panel PNL so that the display panel PNL is not damaged by an external impact. However, as the shear modulus of the third lower adhesive layer 330 decreases, the third lower adhesive layer 330 may reduce the stress applied to the display panel PNL so that the display panel PNL may be assisted in recovery (e.g., recovery of the display panel PNL when transitioning from a folded state to an unfolded state may be improved).

In an embodiment, the third lower adhesive layer 330 may include an elastomer, a cross-linker, and an adhesive resin. The elastomer may have elasticity, and may include, for example, at least one of silicone rubber, urethane rubber, acrylic rubber, styrene-butadiene rubber, polyvinyl chloride, ethylene-propylene copolymer, ethylene-butene copolymer, and ethylene-vinyl acetate copolymer. The elastomer may be cured through thermal curing or UV curing. Curing the elastomer through thermal curing may result in the third lower adhesive layer 330 having a small thickness. The cross-linker may include, for example, a functional group, and the functional group may include at least one of, for example, an alkoxy silane group, a carboxyl group, an acid anhydride group, a vinyl ether group, an amine group, a carbonyl group, an isocyanate group, an epoxy group, an aziridinyl group, a carbodiimide group, and an oxazoline group. The adhesive resin may include, for example, at least one of an acrylic adhesive resin, a silicone adhesive resin, a rubber adhesive resin, a polyester adhesive resin, and a urethane adhesive resin. By properly mixing the elastomer, the cross-linker, and the adhesive resin, physical properties (e.g., shear modulus, creep, adhesive force, etc.) of the third lower adhesive layer 330 may be adjusted.

The third functional layer FL3 may be disposed on a lower surface of the third lower adhesive layer 330. For example, the third functional layer FL3 may directly contact the lower surface of the third lower adhesive layer 330. The third functional layer FL3 may overlap the first flat area PA1, the second flat area PA2, and the folding area FA.

In an embodiment, the third functional layer FL3 may be a support member. For example, the third functional layer FL3 may support the display panel PNL. The third functional layer FL3 may include a metal material having rigidity. For example, the third functional layer FL3 may be made of a metal material such as invar which is an alloy of nickel (“Ni”) and iron (“Fe”), stainless steel (“SUS”), titanium (“Ti”), copper (“Cu”). In addition, the third functional layer FL3 may be connected to a hinge structure that enables folding of the display panel PNL.

In an embodiment, the third functional layer FL3 may include a plurality of openings overlapping the folding area FA. Inclusion of the openings in the third functional layer FL3 may remove the waviness that may be visually recognized by the user.

The bracket BRC may be disposed on a lower surface of the third functional layer FL3. In an embodiment, the bracket BRC overlaps the first flat area PA1 and the second flat area PA2, and does not overlap the folding area FA. The bracket BRC may be disposed at the outermost side the display device 10 to protect the display device 10.

The first upper adhesive layer 410 may be disposed on the display panel PNL. For example, the first upper adhesive layer 410 may be disposed on the upper surface S1 of the display panel PNL. For example, the first upper adhesive layer 410 may directly contact the upper surface S1 of the display panel PNL. The first upper adhesive layer 410 may overlap the first flat area PA1, the second flat area PA2, and the folding area FA.

The first upper adhesive layer 410 may cover the display panel PNL so that the display panel PNL is not damaged by an external impact. In addition, the first upper adhesive layer 410 may adhere the fourth functional layer FL4 to the display panel PNL. For example, the first upper adhesive layer 410 may directly contact the lower surface of the fourth functional layer FL4 and the upper surface S1 of the display panel PNL, thus bonding the lower surface of the fourth functional layer FL4 to the upper surface S1 of the display panel PNL. In addition, when the display panel PNL is folded, the first upper adhesive layer 410 may reduce a stress applied to the display panel PNL. In addition, when the display panel PNL is unfolded, the first upper adhesive layer 410 may assist in recovery of the display panel PNL and may remove the waviness that may be visually recognized by the user.

In an embodiment, the first upper adhesive layer 410 may be an organic adhesive member. For example, the first upper adhesive layer 410 may be an OCA, an OCR, a PSA, etc. When the first upper adhesive layer 410 is the PSA, the PSA may be implemented with, for example, an acrylate-based adhesive, a urethane-based adhesive, or a silicone-based adhesive.

In an embodiment, a shear modulus of the first upper adhesive layer 410 may be about 100 kPa to about 150 kPa at about −25° C. to about −15° C.

As the shear modulus of the first upper adhesive layer 410 increases, the first upper adhesive layer 410 may cover the display panel PNL so that the display panel PNL is not damaged by an external impact. However, as the shear modulus of the first upper adhesive layer 410 decreases, the first upper adhesive layer 410 may reduce the stress applied to the display panel PNL so that the display panel PNL may be assisted in recovery (e.g., recovery of the display panel PNL when transitioning from a folded state to an unfolded state may be improved).

In an embodiment, the first upper adhesive layer 410 may include an elastomer, a cross-linker, and an adhesive resin. The elastomer may have elasticity, and may include, for example, at least one of silicone rubber, urethane rubber, acrylic rubber, styrene-butadiene rubber, polyvinyl chloride, ethylene-propylene copolymer, ethylene-butene copolymer, and ethylene-vinyl acetate copolymer. The elastomer may be cured through thermal curing or UV curing. Curing the elastomer through thermal curing may result in the first upper adhesive layer 410 having a small thickness. The cross-linker may include, for example, a functional group, and the functional group may include at least one of, for example, an alkoxy silane group, a carboxyl group, an acid anhydride group, a vinyl ether group, an amine group, a carbonyl group, an isocyanate group, an epoxy group, an aziridinyl group, a carbodiimide group, and an oxazoline group. The adhesive resin may include, for example, at least one of an acrylic adhesive resin, a silicone adhesive resin, a rubber adhesive resin, a polyester adhesive resin, and a urethane adhesive resin. By properly mixing the elastomer, the cross-linker, and the adhesive resin, physical properties (e.g., shear modulus, creep, adhesive force, etc.) of the first upper adhesive layer 410 may be adjusted.

The fourth functional layer FL4 may be disposed on an upper surface of the first upper adhesive layer 410. For example, the lower surface of the fourth functional layer FL4 may directly contact the upper surface of the first upper adhesive layer 410. The fourth functional layer FL4 may overlap the first flat area PA1, the second flat area PA2, and the folding area FA.

In an embodiment, the fourth functional layer FL4 may be a polarizing layer. The polarizing layer may polarize external light incident on the display panel PNL, and as a result, color reproducibility of the display device 10 may be improved. In an embodiment, the fourth functional layer FL4 may be a sensing layer. The sensing layer may include a plurality of sensing electrodes, and as a result, the display device 10 may sense a user's approach and/or a touch. However, the fourth functional layer FL4 is not limited to the above.

The second upper adhesive layer 420 may be disposed on the first upper adhesive layer 410. For example, the second upper adhesive layer 420 may be disposed on an upper surface of the fourth functional layer FL4, which is disposed between the first upper adhesive layer 410 and the second upper adhesive layer 420. The second upper adhesive layer 420 may overlap the first flat area PA1, the second flat area PA2, and the folding area FA.

The second upper adhesive layer 420 may cover the display panel PNL so that the display panel PNL is not damaged by an external impact. In addition, the second upper adhesive layer 420 may adhere the window WIN to the fourth functional layer FL4. For example, the second upper adhesive layer 420 may directly contact the upper surface of the fourth functional layer FL4 and the lower surface of the window WIN, thus bonding the upper surface of the fourth functional layer FL4 to the lower surface of the window WIN. In addition, when the display panel PNL is folded, the second upper adhesive layer 420 may reduce a stress applied to the display panel PNL. In addition, when the display panel PNL is unfolded, the second upper adhesive layer 420 may assist in recovery of the display panel PNL and may remove the waviness that may be visually recognized by the user.

In an embodiment, the second upper adhesive layer 420 may be an organic adhesive member. For example, the second upper adhesive layer 420 may be an OCA, an OCR, a PSA, etc. When the second upper adhesive layer 420 is a PSA, the PSA may be implemented with, for example, an acrylate-based adhesive, a urethane-based adhesive, or a silicone-based adhesive.

In an embodiment, a shear modulus of the second upper adhesive layer 420 may be about 100 kPa to about 150 kPa at about −25° C. to about −15° C.

As the shear modulus of the second upper adhesive layer 420 increases, the second upper adhesive layer 420 may cover the display panel PNL so that the display panel PNL is not damaged by an external impact. However, as the shear modulus of the second upper adhesive layer 420 decreases, the second upper adhesive layer 420 may reduce the stress applied to the display panel PNL so that the display panel PNL may be assisted in recovery (e.g., recovery of the display panel PNL when transitioning from a folded state to an unfolded state may be improved).

In an embodiment, the second upper adhesive layer 420 may include an elastomer, a cross-linker, and an adhesive resin. The elastomer may have elasticity, and may include, for example, at least one of silicone rubber, urethane rubber, acrylic rubber, styrene-butadiene rubber, polyvinyl chloride, ethylene-propylene copolymer, ethylene-butene copolymer, and ethylene-vinyl acetate copolymer. The elastomer may be cured through thermal curing or UV curing. Curing the elastomer through thermal curing may result in the second upper adhesive layer 420 having a small thickness. The cross-linker may include a functional group, and the functional group may include at least one of, for example, an alkoxy silane group, a carboxyl group, an acid anhydride group, a vinyl ether group, an amine group, a carbonyl group, an isocyanate group, an epoxy group, an aziridinyl group, a carbodiimide group, and an oxazoline group. The adhesive resin may include, for example, at least one of an acrylic adhesive resin, a silicone adhesive resin, a rubber adhesive resin, a polyester adhesive resin, and a urethane adhesive resin. By properly mixing the elastomer, the cross-linker, and the adhesive resin, physical properties (e.g., shear modulus, creep, adhesive force, etc.) of the second upper adhesive layer 420 may be adjusted.

The window WIN may be disposed on the second upper adhesive layer 420. The window WIN may prevent foreign matter such as dust and moisture from penetrating into the display panel PNL, and may protect the display panel PNL from external impact. In an embodiment, the window WIN may be foldable. The window WIN may include, for example, polyimide, polyethersulfone, polyacrylate, polyetherimide, polyethylene naphthalate, polyphenylene sulfide, polyarylate, polycarbonate, polyarylene ether sulfone, polyethylene terephthalate, etc.

As described above, the shear modulus of each of the first to third lower adhesive layers 310, 320, and 330 may be about 200 kPa to about 300 kPa at about −25° C. to about −15° C. In addition, the shear modulus of each of the first and second upper adhesive layers 410 and 420 may be about 100 kPa to about 150 kPa at about −25° C. to about −15° C. Thus, according to embodiments, adhesive layers having a relatively large shear modulus (for example, the first to third lower adhesive layers 310, 320, and 330) may be disposed under the display panel PNL (e.g., on the lower surface S2 of the display panel PNL), and adhesive layers having a relatively small shear modulus (e.g., the first and second upper adhesive layers 410 and 420) may be disposed above the display panel PNL (e.g., on the upper surface S1 of the display panel PNL). Accordingly, the display panel PNL may be protected from an external impact, and folding and unfolding of the display panel PNL may be performed more smoothly.

In an embodiment, each of a first thickness TH1 of the first lower adhesive layer 310, a second thickness TH2 of the second lower adhesive layer 320, and a third thickness TH3 of the third lower adhesive layer 330 may be about 10 um to about 20 um. In addition, the third thickness TH3 may be greater than the second thickness TH2, and the second thickness TH2 may be greater than the first thickness TH1. Thus, according to embodiments, among the lower adhesive layers disposed on the lower surface S2 of the display panel PNL, the thickness of the lower adhesive layer closest to the display panel PNL may be the smallest, the thickness of the lower adhesive layer furthest from the display panel PNL may be the largest, and the thicknesses of the lower adhesive layers may increase as the lower adhesive layers are disposed further away from the display panel PNL.

As the thickness of the lower adhesive layer decreases, the lower adhesive layer may stably support the display panel PNL. Accordingly, since the first lower adhesive layer 310 having a relatively small thickness is disposed closest to the lower surface S2 of the display panel PNL among the lower adhesive layers (e.g., is disposed directly on the lower surface S2 of the display panel PNL), the display panel PNL may be supported more stably.

As the thickness of the lower adhesive layer increases, the lower adhesive layer may reduce a stress applied to the display panel PNL and may assist in recovery of the display panel PNL. Accordingly, since the third lower adhesive layer 330 having a relatively large thickness is disposed furthest from the display panel PNL among the lower adhesive layers, the stress applied to the display panel PNL may be reduced and the display panel PNL may be easily restored.

In an embodiment, a fourth thickness TH4 of the first upper adhesive layer 410 may be greater than the thickness of each of the first to third lower adhesive layers 310, 320, and 330, and a fifth thickness TH5 of the second upper adhesive layer 420 may be greater than the thickness of each of the first to third lower adhesive layers 310, 320, and 330. For example, in an embodiment, each of the fourth and fifth thicknesses TH4 and TH5 may be about 40 um to about 50 um. In an embodiment, the fourth and fifth thicknesses TH4 and TH5 may be about the same as each other. In an embodiment, the fourth and fifth thicknesses TH4 and TH5 may be different from each other.

In an embodiment, each of a glass transition temperature (Tg) of the first lower adhesive layer 310, a glass transition temperature of the second lower adhesive layer 320, and a glass transition temperature of the third lower adhesive layer 330 may be about −40° C. to about −30° C. The glass transition temperature of the first upper adhesive layer 410 and the glass transition temperature of the second upper adhesive layer 420 may be smaller than about −40 C. Adhesive layers having a relatively high glass transition temperature (for example, the first to third lower adhesive layers 310, 320, and 330) may be disposed under the display panel PNL (e.g., on the lower surface S2 of the display panel PNL), and adhesive layers having a relatively low glass transition temperature (for example, the first and second upper adhesive layers 410 and 420) may be disposed above the display panel PNL (e.g., on the upper surface S1 of the display panel PNL). Accordingly, the display panel PNL may be protected from an external impact, and folding and unfolding of the display panel PNL may be performed more smoothly.

As shown in FIG. 3, in an embodiment, each of the first to third lower adhesive layers 310, 320 and 330, and each of the first and second upper adhesive layers 410 and 420, may be disposed in each of the first flat area PA1, the second flat area PA2, and the folding area FA. For example, in an embodiment, each of the first to third lower adhesive layers 310, 320 and 330 and each of the first and second upper adhesive layers 410 and 420 may span the first flat area PA1, the folding area FA, and the second flat area PA2 continuously without any breaks or openings. For example, in an embodiment, each of the first to third lower adhesive layers 310, 320 and 330 and each of the first and second upper adhesive layers 410 and 420 may continuously extend from the first flat area PA1, through the folding area FA, and into the second flat area PA2, without any breaks or openings.

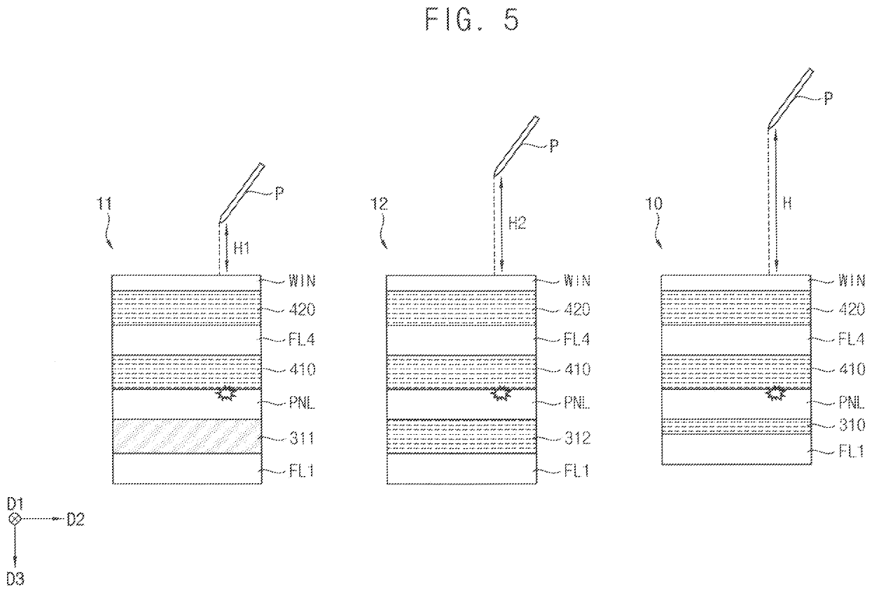

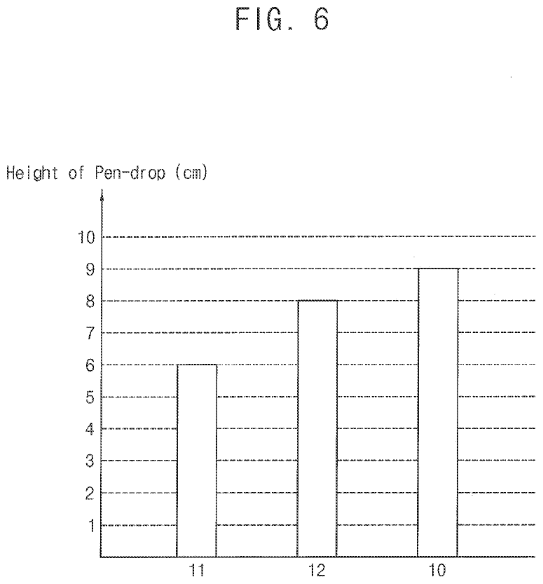

FIGS. 5 and 6 are diagrams illustrating a pen-drop test result according to comparative examples and an embodiment of the present invention.

Referring to FIGS. 5 and 6, the display device 10 used in the pen-drop test includes the first functional layer FL1, the first lower adhesive layer 310, the display panel PNL, the first upper adhesive layer 410, the fourth functional layer FL4, the second upper adhesive layer 420, and the window WIN, which are described above. A first comparative display device 11 according to a first comparative example includes the first functional layer FL1, a first comparative lower adhesive layer 311, the display panel PNL, the first upper adhesive layer 410, the fourth functional layer FL4, the second upper adhesive layer 420, and the window WIN. A second comparative display device 12 according to a second comparative example includes the first functional layer FL1, a second comparative lower adhesive layer 312, the display panel PNL, the first upper adhesive layer 410, the fourth functional layer FL4, the second upper adhesive layer 420, and the window WIN.

The first lower adhesive layer 310 has a shear modulus of about 230 kPa at about −20° C., the first comparative lower adhesive layer 311 has a shear modulus of about 125 kPa at about −20° C., and the second comparative lower adhesive layer 312 has a shear modulus of about 230 kPa at about −20° C. Thus, the shear modulus of the first comparative lower adhesive layer 311 is smaller than the shear modulus of the first lower adhesive layer 310, and the shear modulus of the second comparative lower adhesive layer 312 is the same as the shear modulus of the first lower adhesive layer 310. The pen-drop test may be performed on the first comparative display device 11, the second comparative display device 12, and the display device 10 according to an embodiment of the present invention. For example, the pen P may be dropped onto the window WIN from varying heights. A bright spot may occur on the display panel PNL due to an impact applied to the window WIN. For example, when the pen P is dropped onto the window WIN from a height large enough to cause a damaging impact to the display panel PNL, a bright spot may occur on the display panel PNL.

As shown in FIG. 6, as a result of performing the pen-drop test on the first comparative display device 11, a bright spot does not occur on the display panel PNL until the pen P is dropped from a first height H1 of about 6 cm. As a result of performing the pen-drop test on the second comparative display device 12, a bright spot does not occur on the display panel PNL until the pen P is dropped from a second height H2 of about 8 cm. Thus, the second comparative lower adhesive layer 312 having a larger shear modulus than the first comparative lower adhesive layer 311 provides further protection against deformation of the display panel PNL as a result of an external impact applied to the display panel PNL.

As a result of performing the pen-drop test on the second comparative display device 12, a bright spot does not occur on the display panel PNL until the pen P is dropped from the second height H2 of about 8 cm. In comparison, as a result of performing the pen-drop test on the display device 10 according to an embodiment of the present invention, in which the first lower adhesive layer 310 has a smaller thickness than the second comparative lower adhesive layer 312, a bright spot does not occur on the display panel PNL until the pen P is dropped from a height H of about 10 cm. Thus, the first lower adhesive layer 310 having a relatively smaller thickness than the second comparative lower adhesive layer 312 provides further protection against deformation of the display panel PNL as a result of an external impact applied to the display panel PNL.

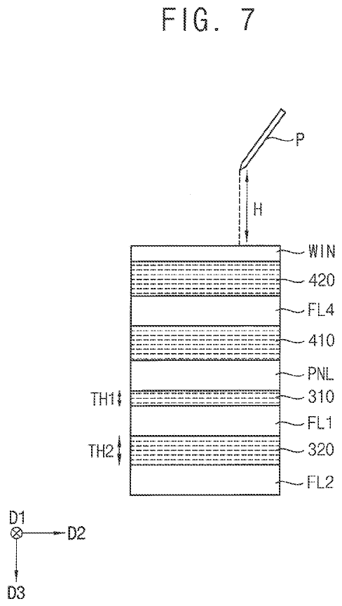

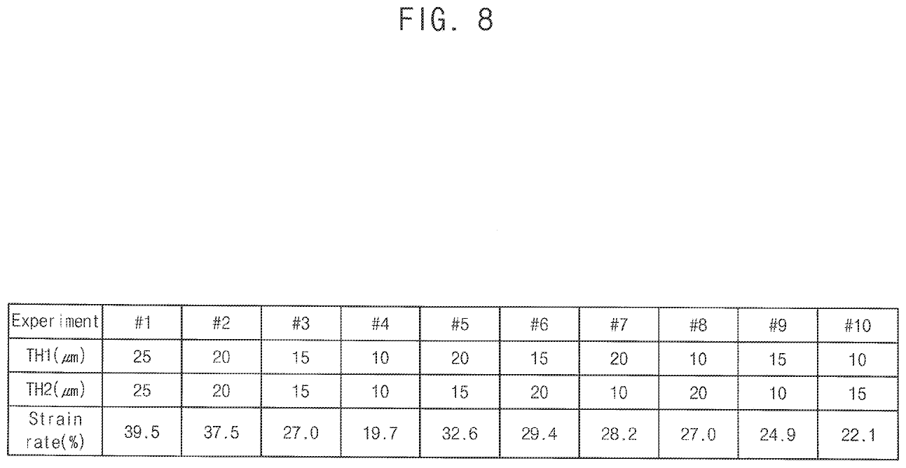

FIGS. 7 and 8 are diagrams illustrating a strain test result according to comparative examples and an embodiment of the present invention.

Referring to FIGS. 7 and 8, the display device 10 used in the strain test includes the second functional layer FL2, the second lower adhesive layer 320, the first functional layer FL1, the first lower adhesive layer 310, the display panel PNL, the first upper adhesive layer 410, the fourth functional layer FL4, the second upper adhesive layer 420, and the window WIN, which are described above. The first lower adhesive layer 310 has the first thickness TH1 and the second lower adhesive layer 320 has the second thickness TH2.

The strain test may be performed on the display device 10. For example, the pen P may be dropped from the same height H while changing the first thickness TH1 and the second thickness TH2. Due to an impact applied to the window WIN, a shape of the display panel PNL may be deformed by a strain rate.

As shown in FIG. 8, Experiments 1, 2, 3, and 4 are experiments performed by setting the first thickness TH1 and the second thickness TH2 to be about equal to each other. When the first thickness TH1 and the second thickness TH2 are about the same, as a sum of the first thickness TH1 and the second thickness TH2 is set smaller, the strain rate of the display panel PNL is measured to be smaller. For example, when the first thickness TH1 and the second thickness TH2 are about 25 um, the strain rate of the display panel PNL is about 39.5%. However, when the first thickness TH1 and the second thickness TH2 are about 10 um, the strain rate of the display panel PNL is about 19.7%.

Experiments 5 and 6 are experiments performed by setting the sum of the first and second thicknesses TH1 and TH2 to about 35 um. When the first thickness TH1 is smaller than the second thickness TH2, the strain rate of the display panel PNL is measured to be smaller. For example, when the first thickness TH1 is about 20 um and the second thickness TH2 is about 15 um, the strain rate of the display panel PNL is about 32.6%. However, when the first thickness TH1 is about 15 um and the second thickness TH2 is about 20 um, the strain rate of the display panel PNL is about 29.4%.

Experiments 7 and 8 are experiments performed by setting the sum of the first and second thicknesses TH1 and TH2 to about 30 um. As described above, when the first thickness TH1 is smaller than the second thickness TH2, the strain rate of the display panel PNL is measured to be smaller. For example, when the first thickness TH1 is about 20 um and the second thickness TH2 is about 10 um, the strain rate of the display panel PNL is about 28.2%. However, when the first thickness TH1 is about 10 um and the second thickness TH2 is about 20 um, the strain rate of the display panel PNL is about 27.0%.

Experiments 9 and 10 are experiments performed by setting the sum of the first and second thicknesses TH1 and TH2 to about 25 um. As described above, when the first thickness TH1 is smaller than the second thickness TH2, the strain rate of the display panel PNL is measured to be smaller. For example, when the first thickness TH1 is about 15 um and the second thickness TH2 is about 10 um, the strain rate of the display panel PNL is about 24.9%. However, when the first thickness TH1 is about 10 um and the second thickness TH2 is about 15 um, the strain rate of the display panel PNL is about 22.1%.

Referring to the pen-drop test result of FIGS. 5 and 6 and the strain test result of FIGS. 7 and 8, it can be seen that as the shear modulus of the lower adhesive layers disposed under the display panel PNL increases, the display panel PNL may be further protected from external impact. In addition, as the sum of the thicknesses of the lower adhesive layers decreases, the display panel PNL may be further protected from external impact. In addition, as the thicknesses of the lower adhesive layers decrease as the lower adhesive layers are disposed closer to the display panel PNL, with the thickness of the lower adhesive layer closest to the display panel PNL being the smallest and the thickness of the lower adhesive layer furthest from the display panel PNL being the largest, the display panel PNL may be further protected from external impact.

The display device 10 according to embodiments may include the first to third lower adhesive layers 310, 320, and 330 described above. The first to third lower adhesive layers 310, 320, 330 may support the display panel PNL so that the display panel PNL is not damaged by an external impact, may reduce a stress applied to the display panel PNL, and may assist in recovery of the display panel PNL.

While the present invention has been particularly shown and described with reference to the embodiments thereof, it will be understood by those of ordinary skill in the art that various changes in form and detail may be made therein without departing from the spirit and scope of the present invention as defined by the following claims.

What is claimed is:

1. A display device, comprising:
a display panel having a folding area and a non-folding area;
a first lower adhesive layer disposed under the display panel in the folding area and the non-folding area and having a first thickness; and
a second lower adhesive layer disposed under the first lower adhesive layer in the folding area and the non-folding area and having a second thickness greater than the first thickness.

2. The display device of claim 1, wherein each of a shear modulus of the first lower adhesive layer and a shear modulus of the second lower adhesive layer is about 200 kPa to about 300 kPa at about −25° C. to about −15° C.

3. The display device of claim 1, wherein each of the first thickness and the second thickness is about 10 um to about 20 um.

4. The display device of claim 1, wherein each of a glass transition temperature of the first lower adhesive layer and a glass transition temperature of the second lower adhesive layer is about −40° C. to about −30° C.

5. The display device of claim 1, further comprising:
a third lower adhesive layer disposed under the second lower adhesive layer in the folding area and the non-folding area and having a third thickness greater than the second thickness.

6. The display device of claim 5, wherein each of a shear modulus of the first lower adhesive layer, a shear modulus of the second lower adhesive layer, and a shear modulus of the third lower adhesive layer is about 200 kPa to about 300 kPa at about −25° C. to about −15° C.

7. The display device of claim 5, wherein each of the first thickness, the second thickness, and the third thickness is about 10 um to about 20 um.

8. The display device of claim 5, wherein each of a glass transition temperature of the first lower adhesive layer, a glass transition temperature of the second lower adhesive layer, and a glass transition temperature of the third lower adhesive layer is about −40° C. to about −30° C.

9. The display device of claim 1, further comprising:
an upper adhesive layer disposed above the display panel in the folding area and the non-folding area.

10. The display device of claim 9, wherein a shear modulus of the upper adhesive layer is smaller than each of a shear modulus of the first lower adhesive layer and a shear modulus of the second lower adhesive layer.

11. The display device of claim 10, wherein the shear modulus of the upper adhesive layer is about 100 kPa to about 150 kPa at about −25° C. to about −15° C.

12. The display device of claim 9, wherein a third thickness of the upper adhesive layer is greater than each of the first thickness and the second thickness.

13. The display device of claim 12, wherein the third thickness of the upper adhesive layer is about 40 um to about 50 um.

14. The display device of claim 9, wherein a glass transition temperature of the upper adhesive layer is smaller than each of a glass transition temperature of the first lower adhesive layer and a glass transition temperature of the second lower adhesive layer.

15. The display device of claim 14, wherein the glass transition temperature of the upper adhesive layer is smaller than about −40° C.

16. A display device, comprising:
a display panel having a folding area and a non-folding area;
an upper adhesive layer disposed above the display panel in the folding area and the non-folding area; and
a lower adhesive layer disposed under the display panel in the folding area and the non-folding area and having a thickness smaller than a thickness of the upper adhesive layer.

17. The display device of claim 16, wherein a shear modulus of the upper adhesive layer is smaller than a shear modulus of the lower adhesive layer.

18. The display device of claim 16, wherein a thickness of the upper adhesive layer is about 40 um to about 50 um, and a thickness of the lower adhesive layer is about 10 um to about 20 um.

19. The display device of claim 16, wherein a glass transition temperature of the upper adhesive layer is less than about −40° C., and a glass transition temperature of the lower adhesive layer is about −40° C. to about −30° C.

20. A display device, comprising:
a display panel including a first non-folding area, a second non-folding area, and a folding area positioned between the first non-folding area and the second non-folding area;
an upper adhesive layer disposed above the display panel and overlapping the folding area;
a first lower adhesive layer disposed under the display panel, overlapping the folding area, having a thickness smaller than a thickness of the upper adhesive layer, and having a shear modulus greater than a shear modulus of the upper adhesive layer; and
a second lower adhesive layer disposed under the first lower adhesive layer, overlapping the folding area, having a thickness smaller than the thickness of the upper adhesive layer and greater than the thickness of the first lower adhesive layer, and having a shear modulus greater than the shear modulus of the upper adhesive layer.

21. A display device, comprising:
a display panel having a folding area and a non-folding area;
an upper adhesive layer disposed on a first surface of the display panel in the folding area and the non-folding area;
a first lower adhesive layer disposed on a second surface of the display panel in the folding area and the non-folding area and having a thickness smaller than a thickness of the upper adhesive layer,
wherein the second surface of the display panel opposes the first surface of the display panel; and
a second lower adhesive layer disposed on the second surface of the display panel in the folding area and the non-folding area and having a thickness greater than the thickness of the first lower adhesive layer,
wherein the first lower adhesive layer is disposed between the display panel and the second lower adhesive layer.

22. The display device of claim 21, wherein the upper adhesive layer directly contacts the first surface of the display panel, and the first lower adhesive layer directly contacts the second surface of the display panel.

23. The display device of claim 21, wherein the upper adhesive layer, the first lower adhesive layer, and the second lower adhesive layer are continuously disposed in the folding area and the non-folding area without any breaks or openings.

24. The display device of claim 21, wherein a shear modulus of the upper adhesive layer is smaller than each of a shear modulus of the first lower adhesive layer and a shear modulus of the second lower adhesive layer.

25. The display device of claim 21, wherein a glass transition temperature of the upper adhesive layer is smaller than each of a glass transition temperature of the first lower adhesive layer and a glass transition temperature of the second lower adhesive layer.
